(19) United States
(12) Patent Application Publication
(10) Pub. No.: US 2007/0037366 A1
(43) Pub. Date: Feb. 15, 2007

(54) METHOD OF CRYSTALLIZING AMORPHOUS SEMICONDUCTOR FILM

(76) Inventor: Hiroki NAKAMURA, Ageo-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/462,575

(22) Filed: Aug. 4, 2006

(30) Foreign Application Priority Data
Aug. 11, 2005 (JP) 2005-233366

(51) Int. Cl. H01L 21/20; H01L 21/00

(52) U.S. Cl. 438/487; 438/482

(57) ABSTRACT

A method of crystallizing a non-monocrystalline semiconductor film, including forming a non-monocrystalline semiconductor film on a substrate, subjecting the non-monocrystalline semiconductor film to a dehydrogenation treatment by way of at least one kind of heat treatment which is selected from the group consisting of irradiating flash lamp beam to a surface of the non-monocrystalline semiconductor film, and blowing a heated inert gas to the surface of the non-monocrystalline semiconductor film, forming a cap film on the surface of the non-monocrystalline semiconductor film, and irradiating, through the cap film, a laser beam to the surface of the non-monocrystalline semiconductor film, the laser beam having a light intensity distribution where the intensity of light increases gradually from a region exhibiting a lowermost light intensity to the periphery of the region, thereby crystallizing the laser beam-irradiated region of the non-monocrystalline semiconductor film.

### CROSS-REFERENCE TO RELATED APPLICATIONS

This application is based upon and claims the benefit of priority from prior Japanese Patent Application No. 2005-233366, filed Aug. 11, 2005, the entire contents of which are incorporated herein by reference.

### BACKGROUND OF THE INVENTION

1. Field of the Invention

This invention relates to a method of crystallizing an amorphous semiconductor film and, in particular, to a method of crystallizing a non-monocrystalline semiconductor layer for obtaining a crystal of large grain size.

2. Description of the Related Art

A switching transistor of a display device such as a liquid crystal display device has been conventionally formed in an amorphous semiconductor film formed on the glass substrate. Since the information to be dealt with is digitized and the processing speed is expected to be further enhanced due to expansion of the IT market, the display device is now demanded to exhibit picture images of further enhanced quality. With a view to meeting such a demand, there have been developed a display device where the switching transistor for switching pixels to each other as well as the transistor of a driving circuit portion are formed in a region of polycrystalline semiconductor film, thereby making it possible to enhance the quality of picture images and to miniaturize the display device.

As for the means for crystallize an amorphous silicon layer that has been formed on the surface of a glass substrate, there has been known an excimer laser annealing method (ELA method). The grain diameter of the crystal that has been obtained from this ELA method however is 0.1 μm or so, so that when a thin-film transistor (TFT) is created in this crystallized region, a large number of crystal boundaries are caused to be included in the channel region of a single thin-film transistor. Therefore, the properties of this thin-film transistor are deteriorated to 200 cm²/Vs in mobility and about 10⁷ in on-off current ratio, both of which being greatly inferior to the properties of an MOS transistor that has been created in a monocrystalline Si layer.

This assignee has previously developed a manufacturing technique which is featured in that an amorphous silicon layer is irradiated with laser beams, thereby making it possible to form crystal grains having as large size as enabling at least one TFT to be created therein. The TFT formed in a single crystal grain in this manner is free from undesirable influences that may be caused due to the presence of crystal boundaries such as non-uniformity in properties of TFT and is enabled to exhibit great improvement in properties of TFT. Furthermore, the TFT formed in a single crystal grain in this manner can be formed into a processor of high quality or into a functional element such as memories and sensors. As for the method of crystallizing such an amorphous silicon film as described above, there are known methods which have been proposed in a document by W. Yeh and M. Matsumura (Jpn. Appl. Phys. Vol. 41(2002) 1909); and in a document by M. Hiramatshu et al (a digest No. 2 for the 63rd autumn lecture meeting, Jpn. Appl. Phys. P779,26a-G-2 [2002]).

In the former document, there is described a method for crystallizing an amorphous silicon film wherein a phase-modulated laser beam of 800 mJ/cm² fluence is irradiated, through a cap film consisting of an SiO₂ film or of a laminated film of SiON/SiO₂, to the amorphous silicon film, thereby enabling crystal grains to laterally grow in the direction parallel with the amorphous silicon film, thus crystallizing the amorphous silicon film.

Further, in the latter document, there is described a method for crystallizing an amorphous silicon film in the lateral direction wherein a homogenized and phase-modulated laser beam is irradiated, through an SiO₂ cap film, to the amorphous silicon film while heating a substrate, thus crystallizing the amorphous silicon film.

Furthermore, JP Patent Laid-open Publication (Kokai) No. 2005-39259 (2005) describes a method of crystallizing a non-monocrystalline semiconductor film wherein at least an SiOₓ film and an SiON film are deposited on the laser beam incident surface of the non-monocrystalline film and then, a laser beam having a light intensity distribution comprising a plurality of inverse triangular patterns in cross-section is irradiated thereto, thus crystallizing the non-monocrystalline semiconductor film.

As described above, in all of the methods described in the above-mentioned documents, laser beam is irradiated onto an amorphous silicon film through a cap film consisting of an SiOₓ film or an SiON film, thereby making it possible to create a crystallized region of large grain diameter. The reason for employing the cap film resides in the fact that the cap film is capable of absorbing the laser beam to accumulate heat therein, which is effective in promoting the growth of crystal grains.

The cap film is very effective in forming a crystallized region of large grain diameter. However, when a step of dehydrogenation which is a pretreatment prior to the crystallization process is performed subsequent to the creation of the cap film by making use of a flash lamp annealing apparatus, almost the entire region of the non-monocrystalline semiconductor film is accompanied with an ablated region.

The non-monocrystalline semiconductor film having such an ablated region is accompanied with problems that the properties thereof are poor and that it is difficult to create an TFT in the ablated region when it is subsequently crystallized.

As a result of extensive study made by the present inventors with regard to the generation of the aforementioned ablation, it has been found that the reasons for the generation of ablation can be attributed to the following facts. Namely, since a non-crystalline semiconductor film such as an amorphous silicon film is created by means of plasma CVD method, a few percentage of hydrogen is included therein. When an amorphous silicon film containing hydrogen in this manner is crystallized by the irradiation of laser beam, the amorphous silicon film is caused to generate ablation, thus raising serious problems. Therefore, it is required to undertake the process of dehydrogenation as a pretreatment prior to the crystallization process.

According to the method set forth in the aforementioned JP patent document, an insulating layer is deposited as a cap film on the laser beam incident surface of the non-monocrystalline semiconductor film and then the non-monocrystalline semiconductor film is subjected to a heat treatment at 570° C. for two hours, thereby executing a dehydrogenation treatment for removing hydrogen from the non-monocrystalline semiconductor film. However, it has been found that if the dehydrogenation treatment is performed in the presence of the cap film, hydrogen cannot be easily extracted from the non-monocrystalline semiconductor film due to the existence of the cap film, thus making it impossible to fully perform the dehydrogenation treatment throughout the entire surface being treated.

Further, it has been also found that in order to fully carry out the dehydrogenation treatment in the presence of the cap film, the heat treatment is required to be performed for a long time in a high-temperature atmosphere. There is however a problem that such a heat treatment requiring high-temperatures and a long time as mentioned above cannot be easily applied to the manufacturing process of a liquid crystal display device where glass is employed as the substrate thereof.

Additionally, unless the cap film is formed following the formation of non-monocrystalline semiconductor film, the non-monocrystalline semiconductor film may be contaminated with impurities. For this reason, the dehydrogenation is usually performed after the formation of the cap film.

### BRIEF SUMMARY OF THE INVENTION

An object of the present invention is to provide a method of crystallizing a semiconductor film which makes it possible to perform the dehydrogenation of a non-monocrystalline semiconductor film without thermally damaging the semiconductor film, without contaminating the semiconductor film with impurities, and without generating the ablation of the semiconductor film.

According to a first aspect to the present invention, there is provided a method of crystallizing a non-monocrystalline semiconductor film, comprising:

forming a non-monocrystalline semiconductor film on a substrate;

subjecting the non-monocrystalline semiconductor film to a dehydrogenation treatment by way of at least one heat treatment selected from the group consisting of irradiating flash lamp beam to a surface of the non-monocrystalline semiconductor film, and blowing a heated inert gas to the surface of the non-monocrystalline semiconductor film;

forming a cap film on the surface of the non-monocrystalline semiconductor film; and

irradiating, through the cap film, a laser beam to the surface of the non-monocrystalline semiconductor film, the laser beam having a light intensity distribution where the intensity of light increases gradually from a region exhibiting a lowermost light intensity to the periphery of the region, thereby crystallizing the laser beam-irradiated region of the non-monocrystalline semiconductor film.

According to a second aspect to the present invention, there is provided an apparatus for manufacturing a substrate to be treated for crystallization, which comprises:

a common chamber formed of an airtight vessel;

a non-monocrystalline semiconductor film-forming chamber for forming a non-monocrystalline semiconductor film, which is formed of an airtight vessel communicating, via a load lock mechanism, with the common chamber;

a dehydrogenation chamber for performing dehydrogenation of the non-monocrystalline semiconductor film, which is formed of an airtight vessel communicating, via a load lock mechanism, with the common chamber; and

an insulating film-forming chamber for forming a cap film and an insulating film including an underlying insulating film, which is formed of an airtight vessel communicating, via a load lock mechanism, with the common chamber.

Advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIGS. 1A to 1D are cross-sectional views illustrating, step-wise, a method of crystallizing a semiconductor film according to one embodiment of the present invention;

FIG. 2 is a cross-sectional view schematically illustrating the construction of a flash lamp apparatus to be employed in a method of crystallizing a semiconductor film according to one embodiment of the present invention;

FIG. 3 is a diagram schematically illustrating the construction of a laser irradiating apparatus to be employed in a method of crystallizing a semiconductor film according to one embodiment of the present invention;

FIG. 4 is a graph showing the light intensity distribution to be employed in a method of crystallizing a semiconductor film according to one embodiment of the present invention; and

FIG. 5 is a diagram schematically illustrating an apparatus for manufacturing a substrate to be treated for crystallization according to another embodiment of the present invention.

### DETAILED DESCRIPTION OF THE INVENTION

The method of crystallizing a semiconductor film according to one aspect of the present invention is characterized in that the surface of a non-monocrystalline semiconductor film is heat-treated in a predetermined manner to perform the dehydrogenation treatment of the non-monocrystalline semiconductor film, then a cap film is deposited on the non-monocrystalline semiconductor film, and laser beam is irradiated, through this cap film, onto the non-monocrystalline semiconductor film, thereby crystallizing the laser-irradiated region of the non-monocrystalline semiconductor film. The heating for effecting the dehydrogenation treatment can be carried out by the irradiation of flash lamp beam to the non-monocrystalline semiconductor film, or by blowing a heated inert gas to the non-monocrystalline semiconductor film.

In this method of crystallizing a semiconductor film, the transfer of the substrate from the step of forming the non-monocrystalline semiconductor film to the step of performing the dehydrogenation treatment should preferably be executed without exposing the substrate to an air atmosphere. The reason is that if the substrate is exposed to an air atmosphere in this transferring stage, the substrate may be contaminated with impurities.

As for the flash lamp to be employed in the dehydrogenation treatment, it is possible to employ a xenon flash lamp. As for the blowing of a high-temperature inert gas to be employed in the dehydrogenation treatment, it can be performed either by the high-velocity scanning of an argon plasma jet or by the blowing of high-temperature nitrogen gas that has been heated in a heating furnace.

The cap film may include a film which is capable of exhibiting absorbability to the wavelength of laser beam. This cap film may be an insulating film selected from the group consisting of an SiO₂ film, an SiOₓ film, an SiON film, an SiN film and a laminate film comprising two or more layers of these films.

The method of crystallizing a semiconductor film according to the first aspect of the present invention may further comprise a step of forming an underlying protective film on the surface of substrate. In this case, the underlying protective film may be an insulating film selected from the group consisting of an SiO₂ film, an SiOₓ film, an SiON film, an SiN film and a laminate film comprising two or more layers of these films.

The laser beam to be employed in the crystallization of the non-monocrystalline semiconductor film should preferably be a laser beam having a light intensity distribution comprising a plurality of inverse triangular patterns in cross-section.

The apparatus for manufacturing a substrate to be treated for crystallization according to the second aspect to the present invention comprises: a common chamber formed of an airtight vessel; a non-monocrystalline semiconductor film-forming chamber for forming a non-monocrystalline semiconductor film, which is formed of an airtight vessel communicating, via a load lock mechanism, with the common chamber; a dehydrogenation chamber for performing dehydrogenation of the non-monocrystalline semiconductor film, which is formed of an airtight vessel communicating, via a load lock mechanism, with the common chamber; and an insulating film-forming chamber for forming a cap film and an insulating film including an underlying insulating film, which is formed of an airtight vessel communicating, via a load lock mechanism, with the common chamber.

This apparatus for manufacturing a substrate to be treated for crystallization can be constructed such that the non-monocrystalline semiconductor film-forming chamber, the dehydrogenation chamber and the insulating film-forming chamber are radially disposed around the common chamber disposed at the center.

In this case, the dehydrogenation chamber may be provided with at least one kind of heat-treating means selected from the group consisting of means for irradiating flash lamp beam, and means for blowing a high-temperature inert gas.

According to the present invention, it is possible to provide a method of crystallizing a semiconductor film as well as a crystallization apparatus which make it possible to perform the dehydrogenation of a semiconductor film without thermally damaging the semiconductor film, and without contaminating the semiconductor film with impurities.

Next, the present invention will be explained with reference to several embodiments.

One of the embodiments of the present invention is directed to a quality-controlled crystallization process which makes it possible to form a cap film subsequent to the step of the dehydrogenation of non-monocrystalline semiconductor film. In this crystallization process, the step of dehydrogenating the non-monocrystalline semiconductor film which is a step to be performed prior to the step of crystallization is executed to the surface of non-monocrystalline semiconductor film in a vacuum after the formation of the non-monocrystalline semiconductor film without permitting the surface of non-monocrystalline semiconductor film to be exposed to an air atmosphere. After finishing this dehydrogenation step, a cap film is formed on the non-monocrystalline semiconductor film in vacuum without permitting the surface of non-monocrystalline semiconductor film to be exposed to an air atmosphere, thus making it possible to perform the dehydrogenation of the non-monocrystalline semiconductor film without the generation of ablation.

Next, the details of this embodiment will be specifically explained with reference to drawings. In these drawings, the same parts are identified by the same symbols, thus omitting the repetition of explanation thereof.

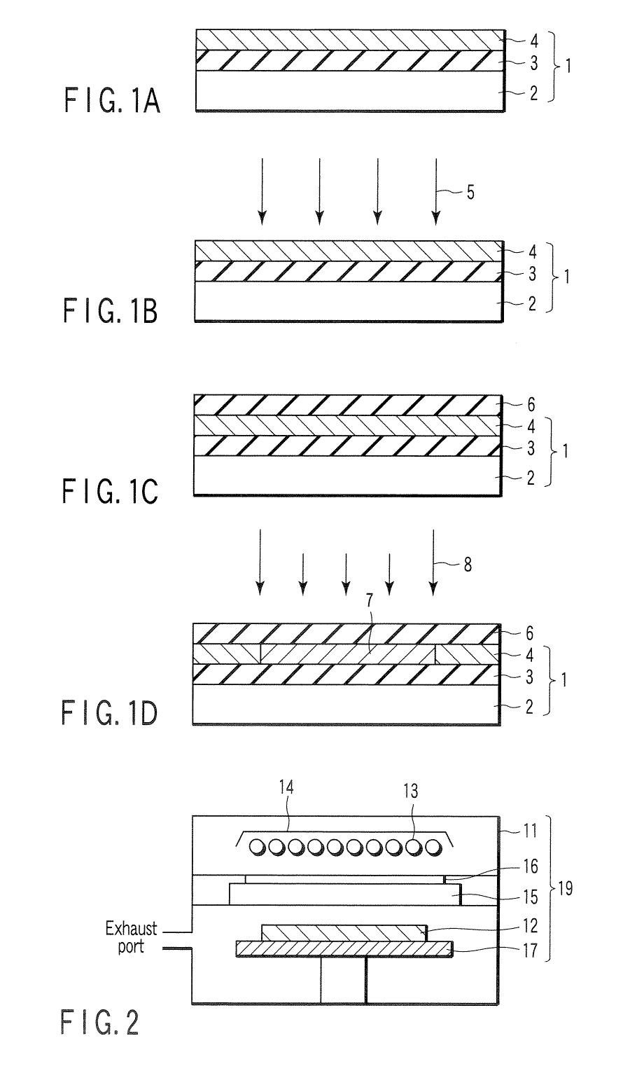

FIGS. 1A to 1D are cross-sectional views illustrating, step-wise, a method of crystallizing a non-monocrystalline semiconductor film according to the first embodiment of the present invention.

First of all, a substrate 1 to be treated (hereinafter referred to as a treating substrate 1) is prepared as shown in FIG. 1A. This treating substrate 1 is a laminated structure comprising a base body formed of a metal plate, an insulating body or a semiconductor body, e.g. a glass substrate 2, on which an underlying protective film 3 and a non-monocrystalline semiconductor film 4 are successively deposited without permitting these components to be exposed to an air atmosphere.

As for the underlying protective film 3, it is possible to employ, for example, a silicon nitride (SiN) film, a silicon oxide (SiO₂) film, or an SiOₓ film exhibiting light absorbability. Herein, the SiOₓ film is a Si-rich oxide film with x being less than 2. It is also possible to employ a laminate structure consisting of the SiN film and the SiO₂ film, or consisting of the SiN film and the SiOₓ film. These films can be formed by means of CVD (for example, a plasma chemical vapor-phase deposition method or a low-pressure chemical vapor-phase deposition method) or by means of a sputtering method. The thickness of the underlying protective film 3 should preferably be about 100 to 800 nm for instance.

Due to the heat-accumulating effect of this underlying protective film 3 having heat-insulating property, this underlying protective film 3 acts not only to prevent the non-monocrystalline semiconductor film 4 from being contaminated and diffused with impurities originating from the glass substrate 2 but also to retard the cooling (temperature-lowering) rate and promote the growth of larger crystal grain on the occasion of the crystallization to be effected by the irradiation of a laser beam in a subsequent step.

This underlying protective film 3 may be formed all over the surface of the glass substrate 2 by means of plasma CVD for instance. The resultant underlying protective film 3 thus formed may be left entirely as it is or may be left partially through the patterning of the underlying protective film 3. In this embodiment, one case where the underlying protective film 3 is left entirely as it is will be explained.

The non-monocrystalline semiconductor film 4 to be formed on the underlying protective film 3 is subjected to crystallization and formed to have a thickness ranging from about 30 to 200 nm. This non-monocrystalline semiconductor film 4 may be an Si film, an Si₁₋ₓGeₓ film or an Si_{1-x-y}GeₓC_{y} film. These non-monocrystalline semiconductor films can be formed by means of CVD (for example, a plasma chemical vapor-phase deposition method or a low-pressure chemical vapor-phase deposition method) or by means of a sputtering method. This non-monocrystalline semiconductor film 4 may be deposited all over the surface of the underlying protective film 3 or formed on a portion of the underlying protective film 3 by means of patterning. In this embodiment, the non-monocrystalline semiconductor film 4 is deposited all over the surface of the underlying protective film 3.

Next, as shown in FIG. 1B, the step of dehydrogenating the non-monocrystalline semiconductor film 4 is successively executed without permitting the non-monocrystalline semiconductor film 4 thus formed to be exposed to an air atmosphere. This dehydrogenation can be executed by at least one kind of heat treatment selected from the group consisting of a method of irradiating flash lamp beam, and a method of blowing a high-temperature inert gas. This dehydrogenation process by any of the method of irradiating flash lamp beam, and the method of blowing a high-temperature inert gas is a heat treatment method enabling the non-monocrystalline semiconductor film 4 to be relatively instantly heated. Further, this dehydrogenation process is characterized in that the dehydrogenation is applied directly to the surface of non-monocrystalline semiconductor film 4 in the absence of other kind of film. Accordingly, the dehydrogenation process can be carried out at low temperatures. Since the dehydrogenation process can be carried out at low temperatures, it is now possible to carry out the manufacturing process of a thin-film transistor at a lower temperature. If it is possible to lower the temperature in the manufacturing process of a thin-film transistor, the materials constituting a display device such as liquid crystal display device can be widely selected. For example, a glass substrate can be replaced by a plastic substrate.

As shown in FIG. 1B, in this embodiment, the non-monocrystalline semiconductor film 4 of the treating substrate 1 is irradiated with beam 5 by making use of a dehydrogenation apparatus 19 such as a flash lamp annealing apparatus as shown in FIG. 2, thereby executing the dehydrogenation of the non-monocrystalline semiconductor film 4. When the beam 5 is irradiated on the non-monocrystalline semiconductor film 4 by making use of the flash lamp annealing apparatus in this manner, the beam 5 is absorbed in the non-monocrystalline semiconductor film 4. Since heat generated in the non-monocrystalline semiconductor film 4 is not conducted to the underlying protective film 3 and glass substrate both having a low heat conductivity, only the non-monocrystalline semiconductor film 4 is heated without heating the substrate. Further, since there is no film on the surface of non-monocrystalline semiconductor film 4 the desorption of hydrogen can be readily achieved within a short period of time, and it is possible to obviate the generation of ablation in a subsequent crystallization step as described below.

As for the flash lamp, it is preferable to employ a xenon (Xe) lamp or a lamp including a minute amount of metal such as metal halide or mercury in a xenon lamp, since these lamps have a light intensity falling within the region ranging from ultraviolet region to visible light region. As for the half band width of pulse of the flash lamp, it may be around 0.1 to 10 ms. Further, it is more preferable for achieving the desorption of hydrogen to employ a pulse having a half band width of as wide as more than 2 ms for example, since the heating time can be prolonged. Furthermore, even if the heating time is short as millisecond order, it is possible to perform a heating at a sufficiently high temperature (500 to 1000° C.) enough to achieve the desorption of hydrogen.

As for the flash lamp annealing, it is preferable to perform it in vacuum or in an inert gas atmosphere such as a nitrogen gas atmosphere, since there is no cap film attached to the surface of non-monocrystalline semiconductor film 4. As for the apparatus for manufacturing a substrate to be treated for crystallization which makes it possible to carry out the aforementioned process, it may be constructed in combination with a cluster tool type apparatus comprising an underlying protective film-forming chamber, a non-monocrystalline semiconductor film-forming chamber and a cap film-forming chamber, each of these chambers being communicated, via a load lock mechanism, with a common chamber as described hereinafter. In the employment of this apparatus for manufacturing a substrate to be treated for crystallization, at least all of the formation of underlying protective film, the formation of non-monocrystalline semiconductor film, the dehydrogenation, and the formation of cap film should preferably be performed in the manner of sheeter where the treating substrate is transferred, via the common chamber, to each of treating chambers without permitting the treating substrate to be exposed to an air atmosphere.

The flash lamp annealing apparatus for executing the dehydrogenation process by way of this flash lamp annealing is provided, as shown in FIG. 2, with an air-tight vessel 11 having a bottom through which the treating substrate 12 is enabled to enter, and with a flash lamp, e.g. a plurality of rod-like xenon flash lamps 13, which are mounted via a light-transmitting plate 15, on a ceiling portion of the vessel 11. Inside the air-tight vessel 11 disposed above the xenon flash lamps 13, there is disposed a reflector 14 for reflecting the beam of light irradiated upward in the direction toward the treating substrate 12. The beam of the xenon flash lamps 13 is permitted to pass through the light-transmitting plate 15 formed, for example, of quartz having permeability to enable to pass therethrough a light of wavelength raging from ultraviolet to visible light region, thus irradiating the treating substrate 12.

Incidentally, for the purpose of enhancing the uniformity of beam, a light diffusion plate 16 may be disposed on the incident beam side, for example, of the light-transmitting plate 15 in the optical path of the xenon flash lamps 13. Further, the plate 17 for sustaining the treating substrate 12 may be provided with heating means, thus making it possible to perform preliminary heating (for example, 250-550° C.). Furthermore, although the heating can be performed over a large area by means of a long xenon flash lamp or a plurality of xenon flash lamps, the irradiation by means of the xenon flash lamp may be performed in such a manner that a plurality of irradiated regions are enabled to overlap with each other so as to heat the entire region desired to be heated. Thus, since the xenon flash lamp enables to heat entirely a large area, it is possible to suppress uneven desorption of hydrogen and uneven laser annealing.

The xenon flash lamp 13 is formed of a glass tube having a cathode on one end thereof and an anode on the other end thereof, each electrode being connected with a capacitor, and encapsulating therein xenon gas. The electricity stored in the capacitor of a driving power source circuit is enabled to flow through the glass tube to generate Joule heat, whereby the xenon gas is heated, thus enabling the glass tube to emit light.

By making use of the irradiation by means of this flash lamp, it is possible, through the adjustment of irradiation energy density and preheating temperature, to expose the non-monocrystalline semiconductor film 4 once or a plurality of times to a beam of the lamp having a pulse width of 0.1 to 10 ms, thereby making it possible to achieve the dehydrogenation through the heating of short period of time.

Incidentally, the dehydrogenation treatment of the non-monocrystalline semiconductor film 4 can be also performed by the method known in the technical field of manufacturing a liquid crystal display device as rapid thermal annealing (RTA), wherein nitrogen gas heated to a high temperature (for example, 600-700° C.) by making use of a heating furnace and a heating pipe is blown to the non-monocrystalline semiconductor film 4 to heat it within a short time of one to several minutes, or wherein a plasma jet consisting of a heated plasma of argon gas, for example, which has been highly densified within a minute region is scanned at a high velocity over the non-monocrystalline semiconductor film 4 to heat it within a short time. Incidentally, even if an inert gas of high temperatures is blown onto the non-monocrystalline semiconductor film 4 in this manner, it is less likely that the glass substrate 2 is substantially damaged since the treating time is very short. The thermal plasma heating using argon gas can perform a high temperature heating (500 to 1000° C.) by changing a scanning speed, and suppress the uneven desorption of hydrogen. Before the heated gas is blown, it is possible to perform a preheating in order to avoid a rapid elevation of temperature.

Next, a cap film 6 is formed on the surface of the non-monocrystalline semiconductor film 4 that has been subjected to the hydrogen desorption (dehydrogenation) treatment as shown in FIG. 1C. As for the cap film 6, it is possible to employ an insulating film such as an SiO₂ film, an SiOₓ film, an SiON film, an SiN film or a laminate film comprising two or more layers of these films. The thickness of the cap film 6 should preferably be 40 to 500 nm, for example about 300 nm.

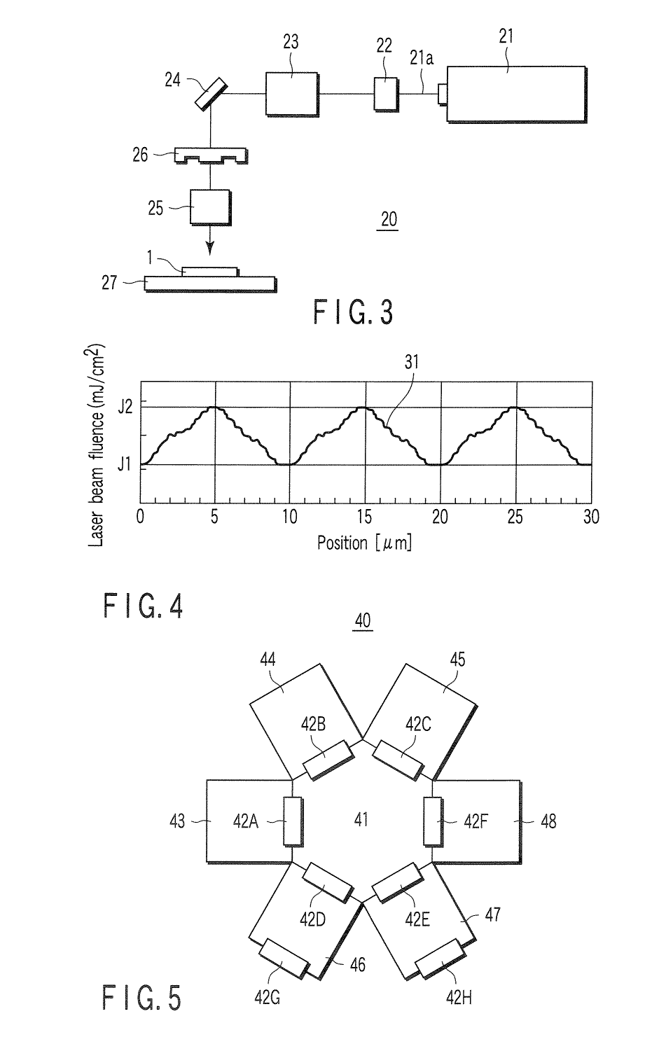

The cap film 6 acts to prevent the surface of the non-monocrystalline semiconductor film 4 from being contaminated with any external impurities or from being contaminated with particles and also acts to accumulate heat therein due to its heat insulating property. Due to this cap film 6, a region of the non-monocrystalline semiconductor film which has been irradiated with the pulse laser beam on the occasion of crystallizing the treating substrate 28 is enabled to melt. As the temperature of this melted region is allowed to become lower after the irradiation of pulse laser beam, the laser beam-irradiated region of the non-monocrystalline semiconductor film 4 is caused to cool very slowly due to the heat-accumulating effect of the cap film 6, thereby causing the solid-liquid interface to move very slowly, thereby making it possible to realize the growth of larger crystal grain. Incidentally, in order to realize this crystal grain size-enlarging effect, it is preferable to employ an SiOₓ film or an SiON film as a material for the cap film 6. In this manner, the substrate 1 to be treated for crystallization is formed. The treating substrate 1 having the cap film 6 formed thereon is delivered to a crystallization apparatus 20 as shown in FIG. 3.

Then, the process of crystallization is executed. As shown in FIG. 1D, the treating substrate 1 is aligned so as to place the surface of the cap film 6 at a predetermined position and then the irradiation of excimer pulse laser beam 8 having a predetermined laser beam intensity distribution is performed. In this embodiment, the irradiation of this laser beam is set to an irradiation position according to the alignment marks which have been set in advance on the treating substrate 1.

The process of crystallization is executed by making use of the laser crystallization apparatus shown in FIG. 3 for instance. As shown in FIG. 3, in the light path of the pulse laser beam 21a that has been emitted from the excimer laser 21, there are successively arranged an attenuator 22 for controlling the energy density (the minimum value J1 and the maximum value J2 shown in FIG. 4) of the laser beam 21a, and a homogenizing optical system 23 for homogenizing the cross-sectional light intensity of laser beam. On the outgoing side of the homogenizing optical system 23, there is disposed, as an optical modulation element, a phase shifter 26 formed of a quartz substrate whose surface is worked with linear steps.

On the outgoing side of the phase shifter 26, there is disposed a projecting (imaging) lens 25 for magnifying or reducing an image. At the focal point on the outgoing side of the projecting lens 25, there is positioned the treating substrate 1 which is mounted on a stage 27. This stage 27 is enabled to move in the direction of X, the direction of Y and the direction of Z and to rotate at an angle of θ, thereby enabling the treating substrate 1 to shift horizontally relative to the phase shifter 26.

In the irradiation of laser beam using this laser crystallization apparatus 20, as the laser beam 21a passes through the phase shifter 26, the energy density of laser beam is phase-modulated into a laser beam intensity distribution 31 where the intensity of laser beam is fluctuated to create a triangular pattern between the minimum beam intensity J1 and the maximum beam intensity J2 as shown in FIG. 4. This laser beam intensity distribution 31 will be recognized as being a laser beam intensity distribution having an inverse triangular pattern in cross-section. Further, this laser beam intensity distribution 31 will be recognized as being a laser beam intensity distribution wherein the intensity of laser beam increases from a region exhibiting the minimum intensity to the peripheral regions thereof. In this case, the minimum value of beam intensity should preferably be such that exceeds over the critical value j1 of the lateral growth condition and that is lower than the melt temperature, and the maximum value of beam intensity should preferably be such that is lower than the critical value j2 of the evaporation of semiconductor film 4 and that is not lower than the melt temperature. These critical values j1 and j2 can be determined mainly depending on the absorption coefficient of the semiconductor film 4 to the laser beam as well as on the thickness of the semiconductor film 4.

When the pulse laser beam 8 is irradiated as described above, the laser beam-irradiated region of the semiconductor film 4 is caused to melt and when the irradiation of laser beam is cut off, the melted region is cooled. The process of this cooling proceeds in such a manner that although the solid-liquid interface shifts to the lower temperature side depending on the beam intensity distribution as shown in FIG. 4, the cooling rate of the semiconductor film 4 is greatly retarded due to the heat-accumulating property of the underlying protective film 3 and of the cap film 6, thereby enabling the crystal growth to take place in the lateral direction, i.e. from the location of the minimum value j1 toward the maximum value j2. As a result, the laser beam-irradiated region 7 of the semiconductor film 4 is crystallized.

As described above, according to the crystallization method of the semiconductor film according to the first embodiment of the present invention, since the dehydrogenation treatment is performed on the non-monocrystalline semiconductor film 4 prior to the deposition of the cap film 6 thereon by way of a rapid heating using a flash lamp apparatus which is provided with a plurality of rod-like xenon flash lamps 13 as shown in FIG. 2, it takes only a very short time in accomplishing the treatment, thus obviating the generation of abrasion and making it possible to effectively perform the dehydrogenation treatment without giving any damage to the glass substrate 2.

Next, the apparatus for manufacturing the substrate to be treated for crystallization according the second embodiment of the present invention will be explained.

FIG. 5 shows a cluster tool type apparatus 40 of sheeter system for manufacturing a substrate to be treated for crystallization according to the second embodiment of the present invention. The fundamental structure of this apparatus for manufacturing a substrate to be treated for crystallization comprises, essentially, a delivery chamber (common chamber) 41 formed of an airtight vessel; an underlying protective film-forming chamber 43 for forming an underlying protective film, which is formed of an airtight vessel and attached via a load lock mechanism 42A to the delivery chamber (common chamber) 41; a non-monocrystalline semiconductor film-forming chamber 44 for forming a non-monocrystalline semiconductor film, which is formed of an airtight vessel and attached via a load lock mechanism 42B to the delivery chamber (common chamber) 41; a dehydrogenation chamber 45 for performing dehydrogenation of the non-monocrystalline semiconductor film, which is formed of an airtight vessel and attached via a load lock mechanism 42C to the delivery chamber (common chamber) 41; a cap film-forming chamber 48 which is formed of an airtight vessel and attached via a load lock mechanism 42F to the delivery chamber (common chamber) 41; a loader chamber 46 for loading the treating glass substrate 1 therein, which is formed of an airtight vessel and attached via a load lock mechanism 42D to the delivery chamber (common chamber) 41; and an unloader chamber 47 for delivering the glass substrate 1, which is formed of an airtight vessel and attached via a load lock mechanism 42E to the delivery chamber (common chamber) 41. Furthermore, the loader chamber 46 is additionally provided with a load lock mechanism 42G for receiving the treating glass substrate 1 which is going to be treated next and housed in advance in a carrier (not shown). Likewise, the unloader chamber 47 is additionally provided with a load lock mechanism 42H for delivering the glass substrate 1 that has been already treated and provided thereon with the cap film 6.

In this manner, the apparatus 40 of cluster tool type for manufacturing a substrate to be treated for crystallization is constructed.

The underlying protective film-forming chamber 43 in this embodiment is a film-forming chamber for executing the plasma CVD of SiO₂ film to thereby form an SiO₂ film as the underlying protective film 3. Incidentally, although the film-forming chamber 48 for forming the cap film 6 is independently disposed in FIG. 5, both of the underlying protective film 3 and the cap film 6 may be formed in the underlying protective film-forming chamber 43 which can be employed not only as the underlying protective film-forming chamber but also as the cap film-forming chamber.

As shown in FIG. 5, the apparatus 40 for manufacturing a substrate to be treated for crystallization is constructed such that the underlying protective film-forming chamber 43, the non-monocrystalline semiconductor film-forming chamber 44, the dehydrogenation chamber 45, the cap film-forming chamber 48, the loader chamber 46 and the unloader chamber 47 are radially arranged around the delivery chamber (common chamber) 41 which is disposed at the center and connected, via the load lock mechanisms 42A, 42B, 42C, 42D, 42E and 42F, with the delivery chamber (common chamber) 41. Furthermore, each of these chambers 43-47 is connected with an exhaust pump for controlling the pressure, thereby enabling executing of the desired treatments as well as the loading and unloading of the treating substrate 1.

The finishing of execution in each step will be followed by the transfer of the treating substrate 1, via the delivery chamber (common chamber) 41, to the next chamber for the next treatment. The pressure inside the delivery chamber (common chamber) 41 is set slightly higher than the pressure in each of these treating chambers to thereby prevent the generation of contamination. Namely, the treating substrate 1 is permitted to enter into or go out of the treating chambers after the pressure inside the delivery chamber (common chamber) 41 has been made slightly higher than the pressure in each of these treating chambers.

Next, the method of manufacturing the substrate to be treated for crystallization will be explained with reference to FIG. 5. In the apparatus 40 shown in FIG. 5, the glass substrate 2 that has been transferred at first to the loader chamber 46 is then transferred, via the delivery chamber 41, to the underlying protective film-forming chamber 43. In this underlying protective film-forming chamber 43, an underlying protective film 3 (for example, an SiOₓ film) is deposited on the surface of the glass substrate 2 by means of plasma CVD method. The glass substrate 2 having the underlying protective film 3 deposited thereon is returned to the delivery chamber 41 and then transferred to the non-monocrystalline semiconductor film-forming chamber 44. In this non-monocrystalline semiconductor film-forming chamber 44, a non-monocrystalline semiconductor film 4 (for example, an amorphous silicon film) is deposited on the underlying protective film 3 by means of plasma CVD method, thus obtaining the treating substrate 1.

The treating substrate 1 having the non-monocrystalline semiconductor film 4 deposited thereon is returned to the delivery chamber 41 and then transferred to the dehydrogenation chamber 45. In this dehydrogenation chamber 45, the treating substrate 1 is subjected to a dehydrogenation treatment by way of flash lamp annealing process by making use of the dehydrogenation apparatus 19 shown in FIG. 2 for instance. The treating substrate 1 dehydrogenated in this manner is returned to the delivery chamber 41 and then transferred to the cap film-forming chamber 48. In this cap film-forming chamber 48, a cap film 6 (for example, an SiOₓ film) is deposited on the treating substrate 1. The treating substrate 1 having the cap film 6 deposited thereon is returned, via the delivery chamber 41, to the unloader chamber 47. Finally, the treating substrate 1 thus treated is transferred to the laser crystallization apparatus 20 shown in FIG. 3 and disposed separately, in which the crystallization of the non-monocrystalline semiconductor film is performed.

In the semiconductor film-forming apparatus constructed as described above, the entire process beginning from the deposition of the underlying protective film 3 in the underlying protective film-forming chamber 43 to the deposition of the cap film 6 in the cap film-forming chamber 48 can be carried out while keeping the air-tightness without the treating substrate being exposed to an air atmosphere. Therefore, even if the dehydrogenation process is carried out with the surface of amorphous silicon substrate being permitted to be exposed, i.e. not covered with the cap film 6, it is possible to avoid the adhesion of foreign matters on the surface of amorphous silicon substrate.

As described above, since the treatment and transfer of the substrate 1 in the process beginning from the step of forming the non-monocrystalline semiconductor film to the step of dehydrogenation are carried out without permitting the treating substrate to be exposed to an air atmosphere, it is possible to obviate any possibility of the non-monocrystalline semiconductor film 4 being contaminated with impurities of air atmosphere on the occasion of performing the dehydrogenation treatment in the dehydrogenation treatment chamber 45 even if the cap film which is necessitated in the conventional method does not exist in this process.

In the embodiment shown in FIG. 5, each of the film-forming chambers and the treatment chambers are radially disposed around the central delivery chamber 41. However, the present invention is not limited to such an arrangement but may be modified such that the treating substrate is enabled to directly move between the film-forming chamber and the neighboring treatment chamber without providing the delivery chamber 41 at the center, wherein the delivery chamber may be interposed as required between the film-forming chamber and the neighboring treatment chamber. Further, these film-forming chambers and treatment chambers may be linearly arrayed with a load locking mechanism being interposed therebetween. Alternatively, these film-forming chambers and treatment chambers may be disposed on the opposite sides of a linearly arrayed delivery chambers with a load locking mechanism being interposed therebetween. Of course it is possible to further provide another crystallization chamber for irradiating a laser beam.

As for the atmosphere in the heating step, it is preferable to perform the heating step in a vacuum or in an inert gas atmosphere. However, the present invention is not limited to such a technique.

As described above, according to the aforementioned embodiments, since the non-monocrystalline semiconductor film is subjected to a dehydrogenation treatment by way of rapid heating treatment prior to the deposition of a cap film on the non-monocrystalline semiconductor film, it is now possible to effectively carry out the dehydrogenation treatment without generating abrasion and without giving any damage to the substrate. Further, since the entire rout in the process beginning from the formation of the non-monocrystalline semiconductor film to the dehydrogenation treatment thereof is kept airtight, the dehydrogenation treatment can be carried out while preventing the contamination of the semiconductor film with impurities even if the cap film is not utilized.

What is claimed is:

1. A method of crystallizing a non-monocrystalline semiconductor film, comprising:
forming a non-monocrystalline semiconductor film on a substrate;
subjecting the non-monocrystalline semiconductor film to a dehydrogenation treatment by way of at least one heat treatment selected from the group consisting of irradiating flash lamp beam to a surface of the non-monocrystalline semiconductor film, and blowing a heated inert gas to the surface of the non-monocrystalline semiconductor film;
forming a cap film on the surface of the non-monocrystalline semiconductor film; and
irradiating, through the cap film, a laser beam to the surface of the non-monocrystalline semiconductor film, the laser beam having a light intensity distribution where the intensity of light increases gradually from a region exhibiting a lowermost light intensity to the periphery of the region, thereby crystallizing the laser beam-irradiated region of the non-monocrystalline semiconductor film.

2. The method according to claim 1, wherein the transfers of the substrate in the steps beginning from the step of forming a non-monocrystalline semiconductor film to the step of dehydrogenation treatment are performed without permitting the substrate to be exposed to an air atmosphere.

3. The method according to claim 1, wherein the flash lamp is a xenon flash lamp.

4. The method according to claim 1, wherein the blowing of inert gas is performed by of high-velocity scanning of argon plasma jet or by blowing nitrogen gas heated to 600 to 700° C. in a heating furnace.

5. The method according to claim 1, wherein the heat treatment is performed in vacuum or in an inert gas atmosphere.

6. The method according to claim 1, wherein the cap film is a film capable of exhibiting absorbability to the laser beam.

7. The method according to claim 6, wherein the cap film is an insulating film selected from the group consisting of an SiO₂ film, an SiOₓ film, an SiON film, an SiN film and a laminate film comprising two or more layers of these films.

8. The method according to claim 1, wherein the cap film has a thickness ranging from 40 to 500 nm.

9. The method according to claim 1, wherein the laser beam has a light intensity distribution comprising a plurality of inverse triangular patterns in cross-section.

10. The method according to claim 1, wherein the non-monocrystalline semiconductor film is a film selected from the group consisting of an Si film, an Si₁₋ₓGeₓ film and an Si_{1-x-y}GeₓC_{y} film.

11. The method according to claim 10, wherein the non-monocrystalline semiconductor film has a thickness ranging from 30 to 200 nm.

12. The method according to claim 1, which further comprises depositing an underlying protective film on the substrate prior to the formation of the non-monocrystalline semiconductor film.

13. The method according to claim 12, wherein the underlying protective film is a film selected from the group consisting of an SiN film, an SiO₂ film, an SiOₓ film (x is a number of not more than 2), a laminate structure consisting of the SiN film and the SiO₂ film, and a laminate structure consisting of the SiN film and the SiOₓ film.

14. The method according to claim 12, wherein the underlying protective film has a thickness ranging from 100 to 800 nm.
